(19) United States
(12) Patent Application Publication
(10) Pub. No.: US 2025/0102579 A1
(43) Pub. Date: Mar. 27, 2025

(54) BATTERY MEASUREMENT JIG AND TEMPERATURE MEASUREMENT JIG

(71) Applicants: TOYOTA SYSTEMS CORPORATION, Nagoya-shi (JP); IVIS INC., Tokyo (JP)

(72) Inventors: Atsushi TAKAGI, Nagoya-shi (JP); Takashi NARUI, Tokyo (JP)

(73) Assignees: TOYOTA SYSTEMS CORPORATION, Nagoya-shi (JP); IVIS INC., Tokyo (JP)

(21) Appl. No.: 18/828,364

(22) Filed: Sep. 9, 2024

(30) Foreign Application Priority Data
Sep. 22, 2023 (JP) 2023-158927

(51) Int. Cl. G01R 31/36; G01K 1/14; G01K 13/00

(52) U.S. Cl. CPC G01R 31/3644; G01K 1/146; G01K 13/00

(57) ABSTRACT

A battery measurement jig includes: a plurality of battery terminal connection portions, each of the battery terminal connection portions including a battery terminal connection portion base including a probe configured to be connected to a battery terminal being a part of a battery and a battery terminal guide; and a flat bar. The battery terminal connection portions are arranged on the flat bar, the battery terminal guide is combined with the battery terminal connection portion base so as to be configured to slide in a battery terminal direction of the battery, and the battery terminal connection portion base is provided on the flat bar with a clearance so as to be configured to move in a direction perpendicular to the battery terminal direction of the battery.

### CROSS-REFERENCE TO RELATED APPLICATION

This application claims priority to Japanese Patent Application No. 2023-158927 filed on Sep. 22, 2023, incorporated herein by reference in its entirety.

### BACKGROUND

### 1. Technical Field

The present disclosure relates to a battery measurement jig and a temperature measurement jig capable of efficiently measuring the performance of a plurality of batteries while reducing human effort necessary for position adjustment of battery terminals.

### 2. Description of Related Art

A technology of checking the battery performance by performing charge and discharge of a secondary battery at the time of manufacturing of the secondary battery or reuse of the secondary battery is known. For example, Japanese Unexamined Patent Application Publication No. 2019-186105 (JP 2019-186105 A) discloses a technology of a charge-discharge apparatus for a plurality of secondary batteries, the charge-discharge apparatus including: a fixing jig capable of fixing the plurality of secondary batteries; a plurality of charge-discharge probes connectable to a plurality of electrode terminals of the plurality of secondary batteries; and a sliding mechanism capable of collectively sliding the plurality of electrode terminals and the plurality of charge-discharge probes in a state in which the plurality of charge-discharge probes is caused to abut against the plurality of electrode terminals by an abutting mechanism capable of causing the plurality of charge-discharge probes to abut against the plurality of electrode terminals.

### SUMMARY

However, in the charge-discharge apparatus in JP 2019-186105 A, when the plurality of batteries is arranged side by side, the plurality of batteries needs to be aligned such that the position of the electrode terminal of each battery out of the plurality of batteries becomes uniform. Therefore, human effort is necessary for advance preparation.

The present disclosure provides a battery measurement jig and a temperature measurement jig capable of efficiently measuring the performance of a plurality of batteries while reducing human effort necessary for position adjustment of battery terminals.

A battery measurement jig according to a first aspect of the present disclosure includes: a plurality of battery terminal connection portions, each of the battery terminal connection portions including a battery terminal connection portion base including a probe configured to be connected to a battery terminal being a part of a battery, and a battery terminal guide; and a flat bar. The battery terminal connection portions are arranged on the flat bar. The battery terminal guide is combined with the battery terminal connection portion base so as to be configured to slide in a battery terminal direction of the battery, and the battery terminal connection portion base is provided on the flat bar with a clearance so as to be configured to move in a direction perpendicular to the battery terminal direction of the battery.

In the battery measurement jig according to the first aspect of the present disclosure, the battery terminal guide may include a first elastic body that supports the battery terminal guide with respect to the battery terminal connection portion base, and a tapered-shape hole that guides the battery terminal. A second elastic body may be provided in the probe. The probe may be configured to slide in the battery terminal direction of the battery. The battery terminal connection portion base may be installed on the flat bar by a first fastening member such that a gap is provided between the flat bar and the battery terminal connection portion base. A diameter of an attachment hole provided on the flat bar or the battery terminal connection portion base may be greater than a diameter of the first fastening member such that the first fastening member is configured to move in a two-dimensional manner in a direction perpendicular to the battery terminal direction.

In the battery measurement jig according to the first aspect of the present disclosure, each of the battery terminal connection portions installed on the flat bar may be connected to the battery terminal of the battery by a fastening clamp at a constant pressure.

In the battery measurement jig according to the first aspect of the present disclosure, each of the battery terminal connection portions installed on the flat bar may be connected to the battery terminal of the battery by a second fastening member.

In the battery measurement jig according to the first aspect of the present disclosure, regarding attachment between the flat bar and the battery terminal connection portion base, an attachment hole on the flat bar or an attachment hole on the battery terminal connection portion base may have an elliptical shape having a long axis in a direction perpendicular to a stacking direction of batteries and the battery terminal direction of the battery.

In the battery measurement jig according to the first aspect of the present disclosure, a battery terminal side distal end of the probe may be positioned closer to the battery terminal connection portion base than a terminal side end portion of the battery terminal guide is in a state before each of the battery terminal connection portions is connected to the battery terminal, and the probe may be connected to the battery terminal after the battery terminal is inserted into a tapered-shape hole and the battery terminal guide comes into contact with the battery terminal.

In the battery measurement jig according to the first aspect of the present disclosure, a connection determination bar may be provided on the battery terminal connection portion base via a third elastic body, the battery terminal guide may include a gauge, the connection determination bar may be configured to be inclined to the battery terminal guide in accordance with a pushing amount of the probe, and whether the probe is appropriately connected to the battery terminal may be determined based on a position of the connection determination bar with respect to the gauge when viewed from a stacking direction of batteries.

A battery measurement jig according to a second aspect of the present disclosure includes: a plurality of battery terminal connection portions respectively including probes configured to be connected to battery terminals of a plurality of batteries configuring a battery unit coupled by a pair of coupling plates; and a flat bar. A placing position of the battery unit is positioned with use of a protrusion or a screw hole provided on a battery unit fixing frame provided on a predetermined battery installation stand, the battery terminal connection portions that respectively abut against the battery terminals of the of batteries are positioned by moving a positioning board provided on the flat bar along the coupling plates, and the battery terminals of the batteries and the probes of the battery terminal connection portions are connected to each other by a fastening clamp provided on the predetermined battery installation stand.

The temperature measurement jig according to a third aspect of the present disclosure is a temperature measurement jig configured such that a thermistor is inserted into a temperature measurement hole in a battery by sliding and measures a temperature of the battery, the temperature measurement jig includes: an upper plate that supports the thermistor; and a lower plate that supports the thermistor. The thermistor includes a fourth elastic body, is positioned in the inner side of an upper plate hole provided in the upper plate and a lower plate hole provided in the lower plate, and is provided in the temperature measurement hole in the battery. Each of the diameter of the upper plate hole and the diameter of the lower plate hole is greater than a diameter of the thermistor such that the thermistor is configured to move in a direction perpendicular to a sliding direction.

In the temperature measurement jig according to the third aspect of the present disclosure, the diameter of the lower plate hole may be greater than the diameter of the upper plate hole.

According to the present disclosure, it becomes possible to efficiently measure the performance of the plurality of batteries while reducing the human effort necessary for the position adjustment of the battery terminals.

### BRIEF DESCRIPTION OF THE DRAWINGS

Features, advantages, and technical and industrial significance of exemplary embodiments of the present disclosure will be described below with reference to the accompanying drawings, in which like signs denote like elements, and wherein:

FIG. 1 is a view showing an overview of a battery measurement jig according to a first embodiment;

FIG. 2 is a diagram showing a system configuration diagram of a battery measurement system according to the first embodiment;

FIG. 3A is a view showing a configuration of a battery terminal connection portion shown in FIG. 1;

FIG. 3B is a view showing a configuration of the battery terminal connection portion shown in FIG. 1;

FIG. 4A is a view for describing the shape of a battery terminal guide shown in FIGS. 3A and 3B;

FIG. 4B is a view for describing the shape of the battery terminal guide shown in FIGS. 3A and 3B;

FIG. 4C is a view for describing the shape of the battery terminal guide shown in FIGS. 3A and 3B;

FIG. 5A is a view for describing the shape of a battery terminal connection portion base shown in FIGS. 3A and 3B;

FIG. 5B is a view for describing the shape of the battery terminal connection portion base shown in FIGS. 3A and 3B;

FIG. 5C is a view for describing the shape of the battery terminal connection portion base shown in FIGS. 3A and 3B;

FIG. 6A is a view for describing the connection between the battery terminal connection portions and a flat bar;

FIG. 6B is a view for describing the connection between the battery terminal connection portions and the flat bar;

FIG. 7A is a view for describing positioning of a battery unit and the flat bar;

FIG. 7B is a view for describing positioning of the battery unit and the flat bar;

FIG. 8A is a view for describing the connection between the battery terminal of a battery module and the battery terminal connection portion;

FIG. 8B is a view for describing the connection between the battery terminal of the battery module and the battery terminal connection portion;

FIG. 8C is a view for describing the connection between the battery terminal of the battery module and the battery terminal connection portion;

FIG. 8D is a view for describing the connection between the battery terminal of the battery module and the battery terminal connection portion;

FIG. 9A is a view showing an overview of a temperature measurement jig;

FIG. 9B is a view showing an overview of the temperature measurement jig;

FIG. 9C is a view showing an overview of the temperature measurement jig;

FIG. 10 is a view showing an overview of a battery ID reading unit;

FIG. 11A is a view showing an overview of a connection determination unit of a battery measurement jig according to a modified example;

FIG. 11B is a view showing an overview of the connection determination unit of the battery measurement jig according to the modified example;

FIG. 11C is a view showing an overview of the connection determination unit of the battery measurement jig according to the modified example; and

FIG. 12 is a view showing an overview of a battery measurement jig according to a second embodiment.

### DETAILED DESCRIPTION OF EMBODIMENTS

Embodiments of a battery measurement jig and a temperature measurement

jig according to the present disclosure are described below with reference to the drawings.

### First Embodiment

### Overview of Battery Measurement Jig

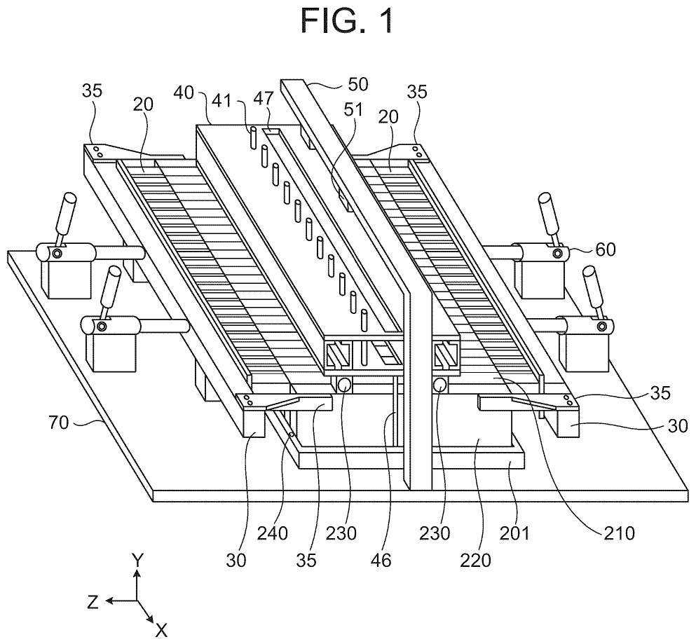

An overview of a battery measurement jig according to a first embodiment is described first. FIG. 1 is a view showing an overview of the battery measurement jig according to the first embodiment. The battery measurement jig is a jig used to collectively measure current-voltage characteristics of a battery unit 200 formed from a plurality of battery modules 210 (can be considered as one example of a “battery” in the claims).

As shown in FIG. 1, the battery measurement jig according to the first embodiment has a plurality of battery terminal connection portions 20, flat bars 30, positioning boards 35, a temperature measurement jig 40, a battery ID reading unit 50, fastening clamps 60, a battery installation stand 70, and a battery unit fixing frame 201.

The battery unit 200 (not shown in FIG. 1) is formed by the plurality of battery modules 210. Specifically, the battery unit 200 is formed by coupling the plurality of battery modules 210 with use of module coupling bars 230 and coupling plates 220.

The battery terminal connection portions 20 are connection portions to be connected to battery terminals 211 of the battery modules 210 that are not shown in FIG. 1. The battery modules 210 are charged and discharged in a state in which the battery terminals 211 are connected to the battery terminal connection portions 20. The battery terminal connection portions 20 are connected to measuring instruments (digital multimeters 100, constant-current power sources 110, and the like) for measuring the current-voltage characteristics of the battery modules 210.

The battery terminal connection portion 20 is formed by a battery terminal guide 21 and a battery terminal connection portion base 22 that are not shown in FIG. 1. The battery terminal connection portion base 22 is attached to the flat bar 30 so as to be movable in the X-axial direction and the Y-axial direction. As a result, misalignment in the attachment positions of the battery terminals 211 of the battery modules 210 is absorbed.

The battery terminal connection portions 20 are attached to be movable in the Z-axial direction such that probes 23 forming a part of the battery terminal guide 21 and the battery terminals 211 of the battery modules 210 are brought into contact with each other in a more reliable manner. The positioning boards 35 are boards fixed to the flat bars 30. The positioning of the plurality of battery terminal connection portions 20 that respectively abut against the battery terminals 211 of the plurality of battery modules 210 is performed by moving the positioning boards along the coupling plates 220.

The temperature measurement jig 40 includes a plurality of thermistors 41, and the temperature of the plurality of battery modules 210 is measured by each thermistor 41. The temperature measurement jig 40 has a battery ID imaging window 47 for imaging two-dimensional barcodes attached to the battery modules 210. The temperature measurement jig 40 is attached to an upper portion of the battery modules 210 with use of a fixing hook 46.

The battery ID reading unit 50 reads out battery module IDs of the plurality of battery modules 210. Specifically, the battery ID reading unit 50 has a plurality of ID readers 51 and reads out two-dimensional barcodes indicating IDs unique to the battery modules 210 attached to the battery modules 210.

The fastening clamps 60 press the plurality of battery terminal connection portions 20 connected to the flat bars 30 against the battery terminals 211 of the plurality of battery modules 210 at a certain pressure. Here, a case where four fastening clamps 60 are used is shown. The battery installation stand 70 is a stand on which the battery unit 200 configured by the plurality of battery modules 210 is installed.

The battery unit fixing frame 201 is a frame for housing the battery unit 200 that is not shown in FIG. 1. The battery unit 200 that is not shown in FIG. 1 is attached to the battery unit fixing frame 201 with use of battery unit positioning screws 240 by metal fittings provided in the coupling plates 220. The battery unit 200 may be attached by providing protrusions on the battery unit fixing frame 201 and fitting the protrusions into depressions provided in the coupling plates 220.

### System Configuration of Battery Measurement System

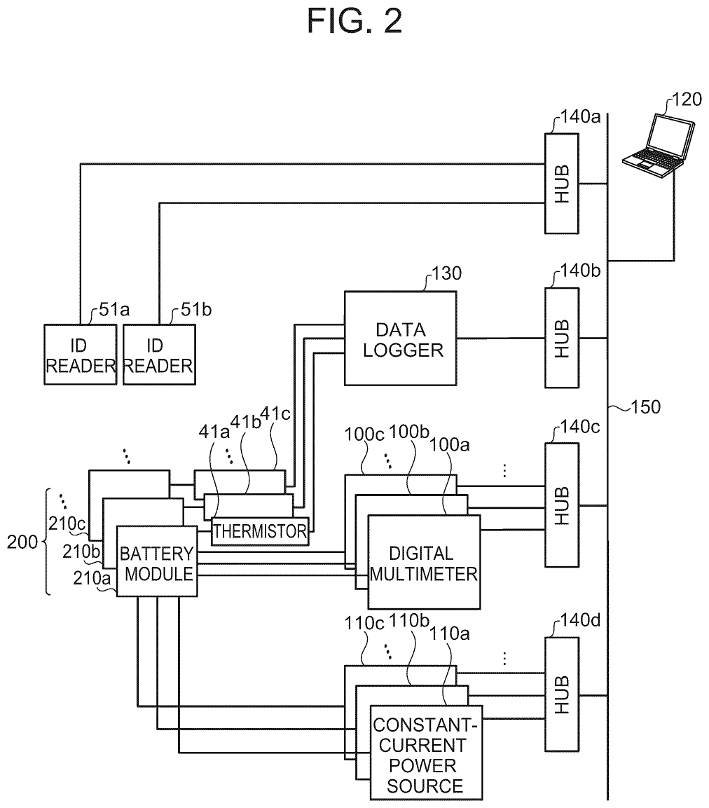

Next, a system configuration of the battery measurement system that measures the current-voltage characteristics of the battery modules 210 is described. FIG. 2 is a diagram showing a system configuration diagram of a battery measurement system according to the first embodiment. As shown in FIG. 2, the battery measurement system has thermistors 41a, 41b, 41c (hereinafter collectively referred to as “thermistors 41”), ID readers 51a, 51b (hereinafter collectively referred to as “ID readers 51”), digital multimeters 100a, 100b, 100c (hereinafter collectively referred to as “digital multimeters 100”), constant-current power sources 110a, 110b, 110c (hereinafter collectively referred to as “constant-current power sources 110”), a laptop PC 120, a data logger 130, and HUBs 140a, 140b, 140c, 140d.

The battery unit 200 is configured by a plurality of battery modules 210a, 210b, 210c (corresponding to the battery modules 210 in FIG. 1). The digital multimeter 100a for measuring the voltage and the current of the battery terminal 211 of the battery module 210a, the constant-current power source 110a that performs the charge and discharge of the battery module 210a, and the thermistor 41a for measuring the battery temperature of the battery module 210a are connected to the battery module 210a, and the thermistor 41a is connected to the data logger 130. The battery modules 210b and 210c also have similar configurations.

The digital multimeter 100a is connected to the HUB 140c, and data measured by the digital multimeter 100a is transmitted to the laptop PC 120 over a LAN 150. The constant-current power source 110a is connected to the HUB 140d and is connected to the laptop PC 120 over the LAN 150. The data logger 130 is connected to the HUB 140b, and the temperature of the battery module 210a measured by the thermistor 41a is transmitted to the laptop PC 120 via the data logger 130, the HUB 140b, and the LAN 150.

The unique two-dimensional barcodes applied to the battery modules 210a, 210b, 210c are read by the ID reader 51a or the ID reader 51b and are transmitted to the laptop PC 120 via the HUB 140a and the LAN 150.

The laptop PC 120 transmits a control signal that controls the constant-current power sources 110 and receives current data and voltage data measured by the digital multimeters 100, temperature data acquired by the data logger 130, and ID data read out by the ID readers 51. The laptop PC 120 can perform analysis of charge-discharge characteristics of the battery modules 210 with use of the current data, the voltage data, the temperature data, and the ID data.

### Configuration of Battery Terminal Connection Portion 20

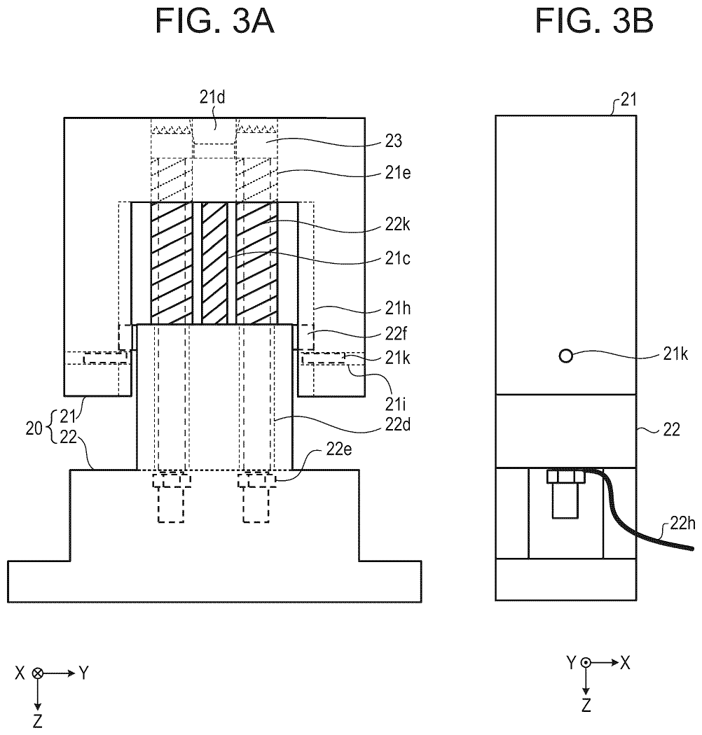

Next, the configuration of the battery terminal connection portion 20 is described. FIGS. 3A and 3B are views showing a configuration of the battery terminal connection portion 20 shown in FIG. 1. As shown in FIGS. 3A and 3B, the battery terminal connection portion 20 has a battery terminal guide 21, a battery terminal connection portion base 22, and the probes 23. The battery terminal guide 21 has a tapered-shape hole 21d, probe holes 21e, guide grooves 21h, and guide retaining screw holes 21i.

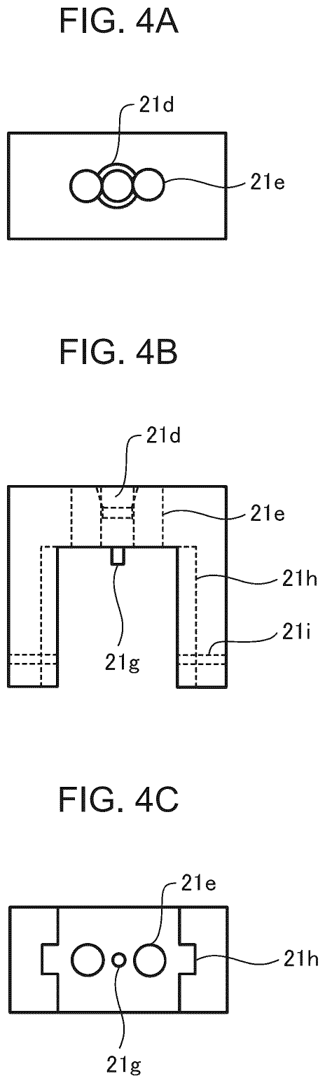

The tapered-shape hole 21d is a hole for adjusting the positions of the battery terminal 211 of the battery module 210 and the battery terminal connection portion 20, and is a hole having a tapered shape that becomes narrower from an upper portion toward a lower portion of the battery terminal guide 21 (see FIG. 4A). The probe holes 21e are holes for inserting the probes 23 and are a pair of through-holes having the same diameter on both sides of the tapered-shape hole 21d (see FIG. 4A and FIG. 4B).

The guide grooves 21h are grooves for fitting guide protrusions 22f described below. The battery terminal connection portion base 22 becomes movable in the Z-axial direction by those guide grooves 21h. Guide retaining screws 21k are inserted into the guide retaining screw holes 21i. The guide retaining screws 21k are screws that pass through the guide retaining screw holes 21i and are for preventing the guide protrusions 22f inserted into the guide grooves 21h from falling out.

The battery terminal connection portion base 22 has probe holes 22d and guide protrusions 22f. The probe holes 22d are through-holes for inserting the probes 23. The guide protrusions 22f are protrusions that are inserted into the guide grooves 21h provided in the battery terminal guide 21 and are provided such that the battery terminal guide 21 moves along the guide grooves 21h. When the guide protrusions 22f are inserted into the guide grooves 21h, the battery terminal guide 21 is placed in a state of being fitted into the battery terminal connection portion base 22.

The battery terminal guide 21 is supported by the battery terminal connection portion base 22 having the guide protrusions 22f and has the guide grooves 21h and a supporting spring 21c (can be considered as one example of a first elastic body in the claims).

When the battery terminal 211 is not in contact with the battery terminal guide 21 in a state in which the battery terminal guide 21 is fitted onto the battery terminal connection portion base 22, the guide protrusions 22f of the battery terminal connection portion base 22 are maintained in a state of being in contact with the guide retaining screws 21k.

The probes 23 are inserted into the probe holes 21e in the battery terminal guide 21 and the probe holes 22d in the battery terminal connection portion base 22 so as to pass therethrough, and are applied with tension in the-Z-axial direction by probe springs 22k (can be considered as one example of a second elastic body in the claims).

The probes 23 are maintained so as not to fall out from the battery terminal connection portion base 22 by probe fixing nuts 22e. A cable 22h connected to the digital multimeters 100 and the constant-current power sources 110 that are not shown in FIGS. 3A and 3B is connected to the probe fixing nuts 22e of the probes 23.

### Shape of Battery Terminal Guide 21

Next, the shape of the battery terminal guide 21 is described. FIGS. 4A to 4C are views for describing the shape of the battery terminal guide 21 shown in FIGS. 3A and 3B. As shown in FIG. 4A, the tapered-shape hole 21d and the probe holes 21e are provided in an upper portion of the battery terminal guide 21.

As shown in FIG. 4B, the battery terminal guide 21 has an inverted U-shape, and the tapered-shape hole 21d is provided in a predetermined depth. The probe holes 21e are provided to pass through the battery terminal guide 21. A supporting spring fixing protrusion 21g and the guide grooves 21h are included on the inner side of the battery terminal guide 21.

The supporting spring fixing protrusion 21g is a protrusion into which the supporting spring 21c is inserted. The guide retaining screw holes 21i into which the guide retaining screws 21k are inserted are included such that the guide protrusions 22f provided on the battery terminal connection portion base 22 do not fall out. As shown in FIG. 4C, the guide grooves 21h in the battery terminal guide 21 are provided in a central portion on the inner side of the battery terminal guide 21 at a predetermined width.

### Shape of Battery Terminal Connection Portion Base 22

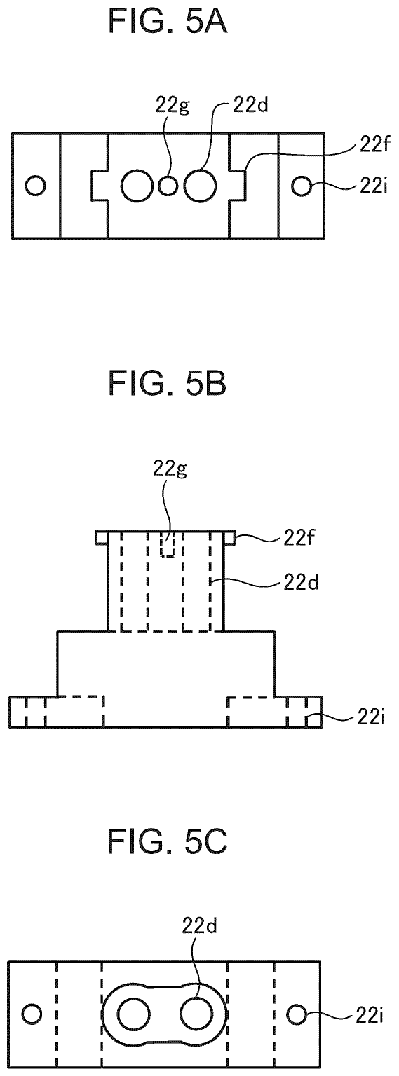

Next, the shape of the battery terminal connection portion base 22 is described. FIGS. 5A to 5C are views for describing the shape of the battery terminal connection portion base 22 shown in FIGS. 3A and 3B. As shown in FIGS. 5A to 5C, the probe holes 22d, the guide protrusions 22f, and a supporting spring insertion hole 22g are included in an upper surface of the battery terminal connection portion base 22 (see FIG. 5A).

As shown in FIG. 5B, the probe holes 22d are provided so as to pass through upper projecting portions of the battery terminal connection portion base 22. The guide protrusions 22f are protrusions having a predetermined length. The supporting spring insertion hole 22g is a hole having a predetermined depth. As shown in FIG. 5C, battery-terminal-connection-portion-base fixing holes 22i for performing connection to the flat bar 30 that is not shown in FIGS. 5A to 5C are provided in a bottom surface of the battery terminal connection portion base 22.

### Connection between Battery Terminal Connection Portions 20 and Flat Bar 30

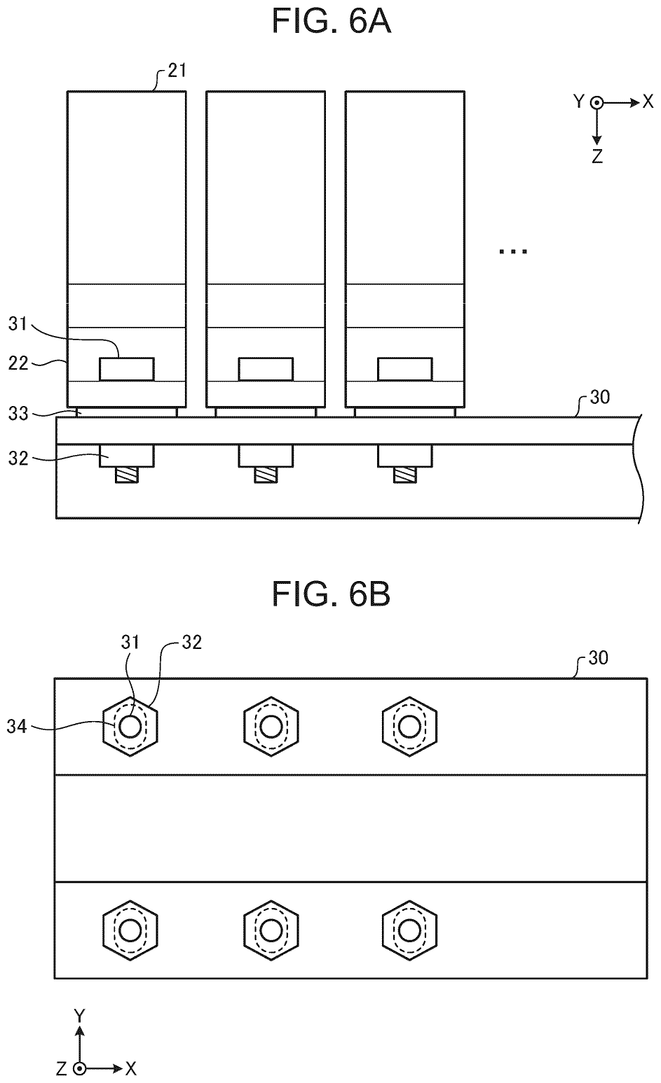

Next, the connection between the battery terminal connection portions 20 and the flat bar 30 is described. FIGS. 6A and 6B are views for describing the connection between the battery terminal connection portions 20 and the flat bar 30. As shown in FIG. 6A, each battery terminal connection portion 20 configured by the battery terminal guide 21 and the battery terminal connection portion base 22 is connected with use of a bolt 31 (can be considered as one example of a “first fastening member” in the claims), a nut 32, and a washer 33.

Specifically, the bolt 31 is inserted from the battery terminal connection portion 20 side, the washer 33 is interposed between the battery terminal connection portion 20 and the flat bar 30, and connection is performed with use of the nut 32 from the flat bar 30 side. Here, the nut 32 is attached with a predetermined torque such that the battery terminal connection portion 20 is movable in the X-axial direction and the Y-axial direction.

As shown in FIG. 6B, attachment holes 34 provided in the flat bar 30 have elliptical shapes larger than the diameter of the bolts 31 such that the battery terminal connection portions 20 are movable in the X-axial direction and the Y-axial direction. The elliptical shape is an elliptical shape having a long axis perpendicular to the stacking direction of the battery modules 210. The attachment hole provided in the battery terminal connection portion base may have a similar elliptical shape.

### Positioning of Battery Unit 200 and Flat Bar 30

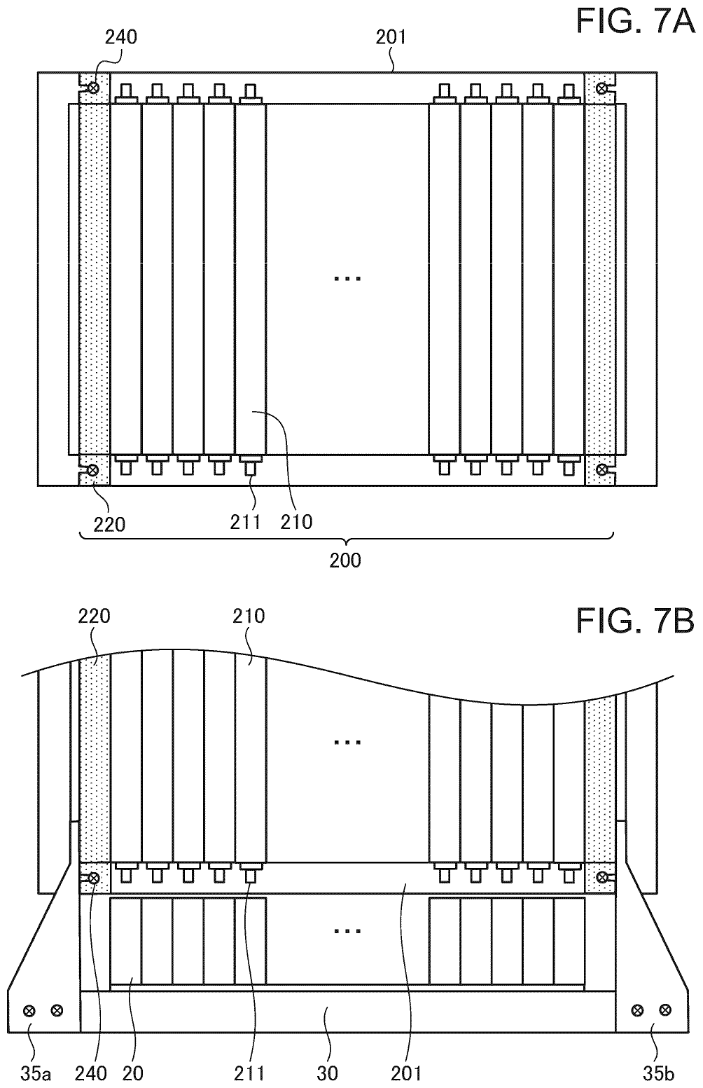

Next, the positioning of the battery unit 200 configured by the plurality of battery modules 210 and the flat bar 30 is described. FIGS. 7A and 7B are views for describing the positioning of the battery unit 200 and the flat bar 30.

As shown in FIG. 7A, the battery unit 200 is fitted in the battery unit fixing frame 201 provided on the battery installation stand 70 that is not shown in FIGS. 7A and 7B, and is attached to the battery unit fixing frame 201 with use of the battery unit positioning screws 240 by metal fittings provided in the coupling plates 220. It is also possible to attach the battery unit 200 by providing protrusions on the battery unit fixing frame 201 and fitting the protrusions into depressions provided in the coupling plates 220.

As shown in FIG. 7B, the flat bar 30 is installed in a predetermined position

in the battery unit 200 with use of positioning boards 35a, 35b (corresponding to the positioning boards 35 in FIG. 1) attached to the flat bar 30. Specifically, the flat bar 30 is moved along the two coupling plates 220 on both sides of the battery unit 200 with use of the positioning boards 35a, 35b. As a result, the flat bar 30 including the battery terminal connection portions 20 can be installed in a predetermined position.

### Connection between Battery Terminal 211 of Battery Module 210 and Battery Terminal Connection Portion 20

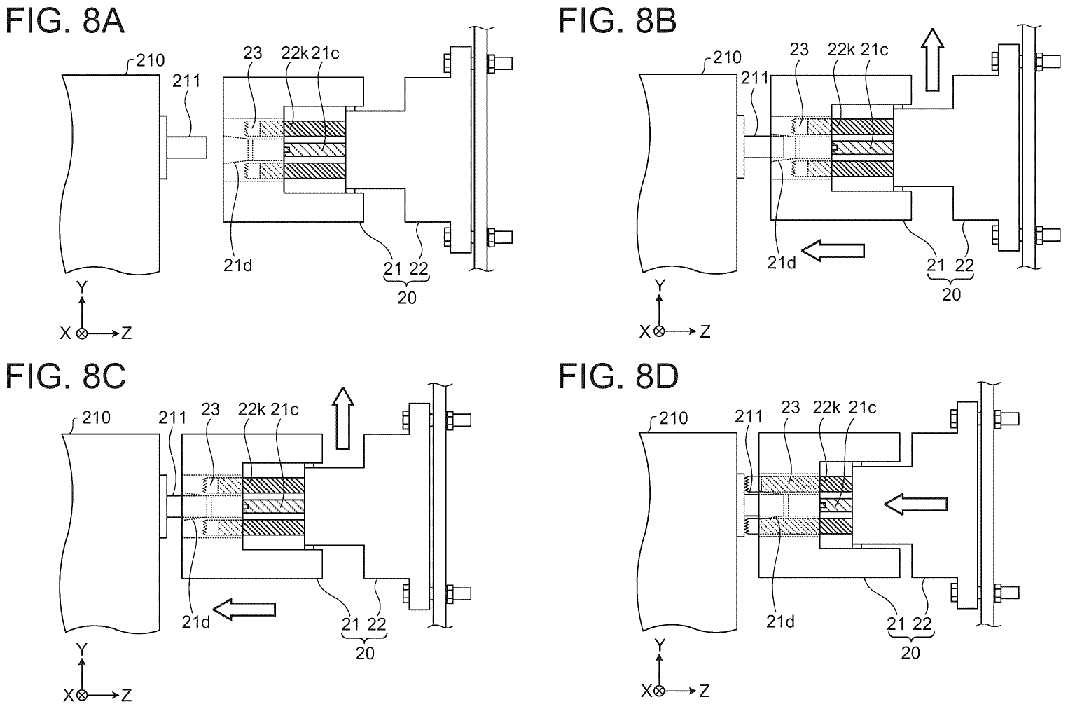

Next, the connection between the battery terminal 211 of the battery module 210 and the battery terminal connection portion 20 is described. FIGS. 8A to 8D are views for describing the connection between the battery terminal 211 of the battery module 210 and the battery terminal connection portion 20. Here, how connection is performed when the battery terminal 211 of the battery module 210 and a connection portion of the battery terminal connection portion 20 are misaligned with each other in the Y-axial direction is described.

As shown in FIG. 8A, in a state before the battery terminal connection portion 20 (the battery terminal guide 21 and the battery terminal connection portion base 22) is connected to the battery terminal 211 of the battery module 210, the battery terminal connection portion 20 is in a state of being misaligned with respect to the battery terminal 211 of the battery module 210 in the-Y-axial direction. In this state, battery terminal side distal ends of the probes 23 are positioned closer to the battery terminal connection portion base 22 side than a terminal side end portion of the battery terminal guide 21.

As shown in FIG. 8B, when the battery terminal connection portion 20 is pushed into the battery terminal 211 side, the battery terminal 211 hits a tapered portion of the tapered-shape hole 21d provided in the battery terminal guide 21, and the battery terminal connection portions 20 moves in the +Y-axial direction along the tapered shape. When the battery terminal connection portion 20 is further pushed into the battery terminal 211 side, the battery terminal connection portion 20 further moves in the +Y-axial direction, the battery terminal 211 hits a bottom of the tapered-shape hole 21d, and misalignment between the battery terminal 211 and the battery terminal guide 21 in the Y-axial direction is adjusted as shown in FIG. 8C.

Then, when the battery terminal connection portion 20 is further pushed in, the battery terminal connection portion base 22 is pushed in into the battery terminal 211 direction (battery terminal direction) and the probes 23 are connected to the battery terminal 211 as shown in FIG. 8D. Here, the probes 23 are connected to the battery terminal 211 by the probe springs 22k attached to the probes 23 by a predetermined pressure. The battery terminal direction in the present disclosure is a direction in which the battery terminal extends.

### Overview of Temperature Measurement Jig 40

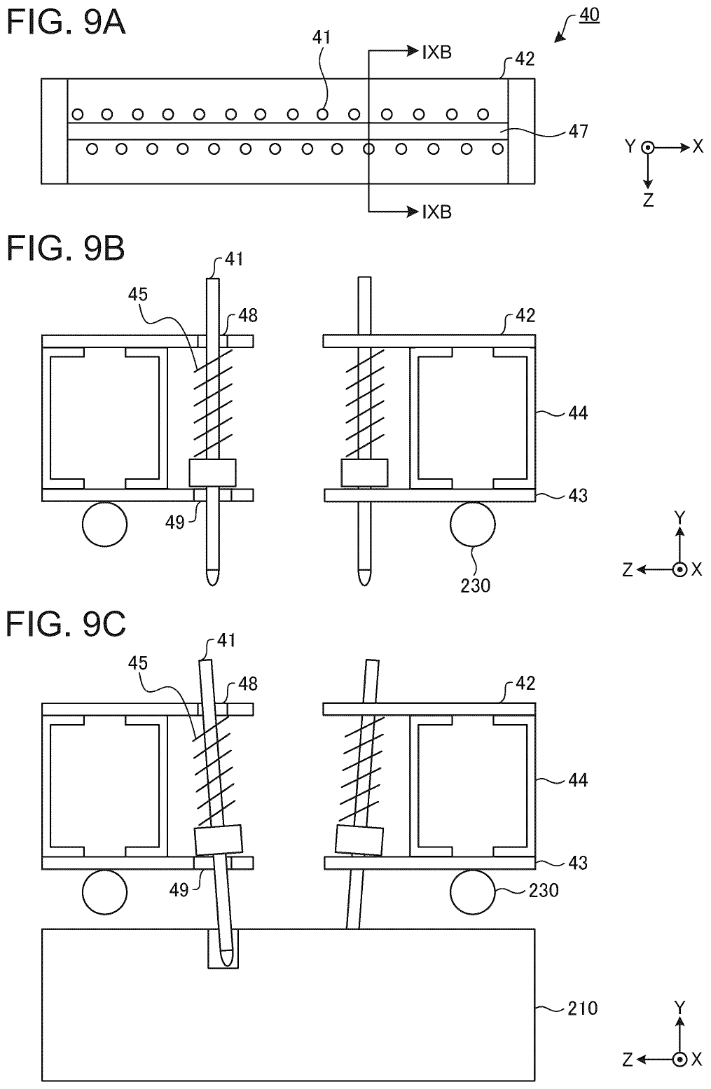

Next, an overview of the temperature measurement jig 40 shown in FIG. 1 is described. FIGS. 9A to 9C are views showing an overview of the temperature measurement jig 40. As shown in FIGS. 9A to 9C, the plurality of thermistors 41 is mounted on the temperature measurement jig 40 in order to measure the temperature of each battery module 210 of the plurality of battery modules 210. The battery ID imaging window 47 is provided in the temperature measurement jig 40 in order to read out two-dimensional barcodes for individual identification respectively attached to the battery modules 210 by the battery ID reading unit 50 described later.

FIG. 9B is a sectional view taken along an IXB-IXB plane in FIG. 9A. As shown in FIG. 9B, the temperature measurement jig 40 has an upper plate 42, a lower plate 43, a plate fixing portion 44, and a compression spring 45 (can be considered as one example of a “fourth elastic body” in the claims). The upper plate 42 has upper plate holes 48 for inserting the thermistors 41. The lower plate 43 has lower plate holes 49 for inserting the thermistors 41.

The thermistor 41 passes through the compression spring 45, the upper plate hole 48, the lower plate hole 49, and is inserted into a temperature measurement hole (not shown) provided in the battery module 210. Here, the upper plate holes 48 provided in the upper plate 42 and the lower plate holes 49 provided in the lower plate 43 are holes having a diameter greater than the diameter of the thermistors 41 such that the thermistors 41 can move in directions (the X-axial direction and the Z-axial direction) perpendicular to the insertion direction of the thermistors 41.

As shown in FIG. 9C, the diameter of the lower plate holes 49 provided in the lower plate 43 is a diameter greater than the diameter of the upper plate holes 48 provided in the upper plate 42 so as to absorb the position misalignment of the temperature measurement holes of the battery modules 210. The temperature measurement jig 40 is installed on an upper portion of the module coupling bars 230 that couple the plurality of battery modules 210 for forming the battery unit 200, and is attached with use of the fixing hook 46 not shown in FIGS. 9A to 9C.

### Overview of Battery ID Reading Unit 50

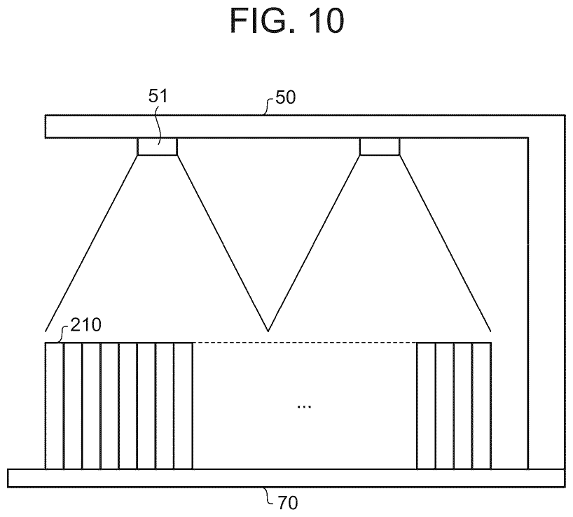

Next, an overview of the battery ID reading unit 50 is described. FIG. 10 is a view showing an overview of the battery ID reading unit 50. Here, the temperature measurement jig 40 installed on an upper portion of the battery modules 210 is omitted for convenience of description.

As shown in FIG. 10, the battery ID reading unit 50 has the plurality of ID readers 51. The ID readers 51 are readers that read out the two-dimensional barcode applied to the upper portion of each battery module 210. Here, two ID readers 51 are disposed, and two-dimensional barcodes of the plurality of battery modules 210 configuring the battery unit 200 are read out. For example, when 28 battery modules 210 configure the battery unit 200, and each of the two-dimensional barcodes of 14 battery modules 210 is read out by one ID reader 51.

As described above, in the present first embodiment, the battery measurement jig fixes the plurality of battery terminal connection portions 20 such that the battery terminals 211 of the plurality of battery modules 210 configuring the battery unit 200 can be movable in the X-axial direction and the Y-axial direction of the flat bar 30, the battery terminal connection portions 20 are connected to the battery terminals 211 with use of the fastening clamps 60, and the current-voltage characteristics of the plurality of battery modules 210 are measured all at once. The battery terminal connection portion 20 has the battery terminal guide 21, the battery terminal connection portion base 22, and the probes 23, the tapered-shape hole 21d is provided in the battery terminal guide 21, and the battery terminal 211 can adjust the position misalignment between the battery terminal connection portion 20 and the battery terminal 211 as a result of the battery terminal connection portion 20 moving in the X-axial direction and the Y-axial direction by using the tapered-shape hole 21d as a guide. The probes 23 are configured to be connected to the battery terminal 211 of the battery module 210 after the correction of the position misalignment between the battery terminal connection portion 20 and the battery terminal 211. Therefore, the performance of the plurality of batteries can be efficiently measured while human effort necessary for position adjustment of the battery terminals 211 can be reduced.

### Modified Example

Next, a modified example of the battery measurement jig is described. Here, a case in which a connection determination unit 80 is provided on each of the battery terminal connection portions 20 and connection determination can be easily performed by the connection determination unit 80 is described.

### Overview of Connection Determination Unit 80

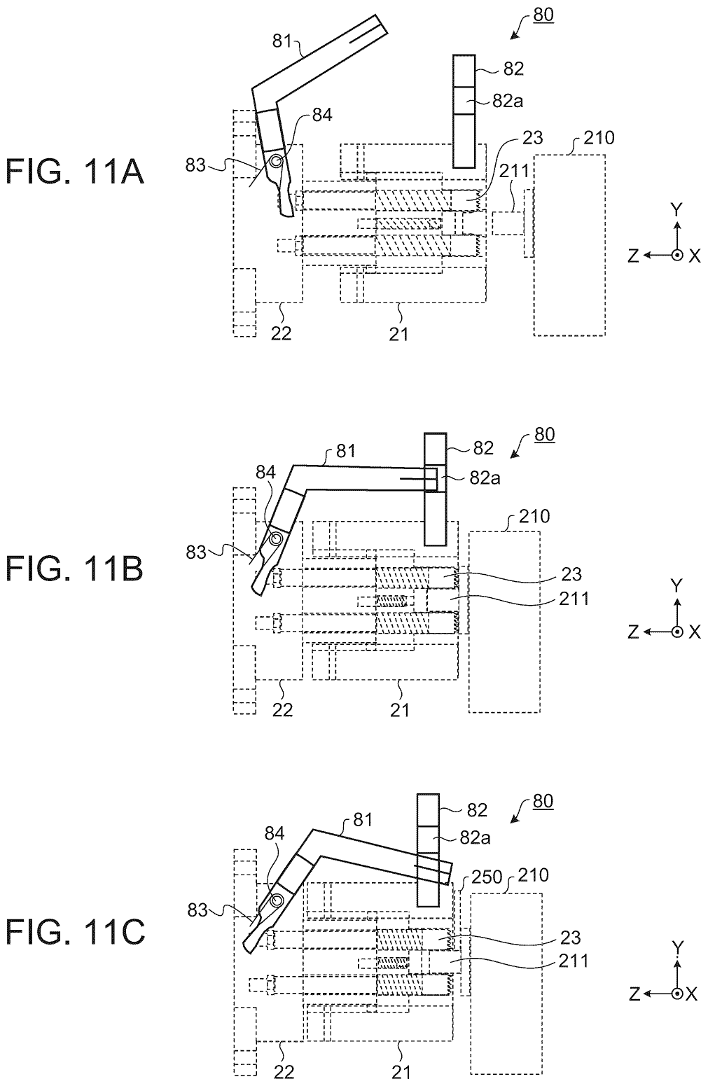

FIGS. 11A to 11C are views showing an overview of the connection determination unit 80 of the battery measurement jig according to the modified example. Sections similar to those in the first embodiment are denoted by the same reference characters, and description thereof is omitted. As shown in FIG. 11A, the connection determination unit 80 has a connection determination bar 81, a gauge 82, a torsion spring 83 (can be considered as one example of a “third elastic body” in the claims), and a connection determination bar supporting portion 84.

The connection determination bar 81 is rotatably attached to the battery terminal connection portion base 22 by the connection determination bar supporting portion 84. The connection determination bar 81 is provided such that one end is in contact with a lower portion of the probe 23, and the connection determination bar 81 rotates such that the other end of the connection determination bar 81 approaches the battery terminal guide 21 when the probe 23 is pushed in the Z-axial direction. When the battery terminal connection portion 20 is not in contact with the battery terminal 211 of the battery module 210, the connection determination bar 81 is positioned in a place far from the battery terminal guide 21 by a force of the torsion spring 83.

As shown in FIG. 11B, when the battery terminal guide 21 comes into contact with the battery terminal 211 of the battery module 210 and the battery terminal connection portion base 22 is pushed into the battery terminal 211 side, the probes 23 come into contact with the battery terminal 211, and end surfaces of the probes 23 on the side opposite from the battery terminal side are put out to the inner side of the battery terminal connection portion base 22. When the probes 23 are pushed out in the Z-axial direction on the inside of the battery terminal connection portion base 22, the connection determination bar 81 of the connection determination unit 80 rotates about the connection determination bar supporting portion 84 so as to overlap with the gauge 82. When the probes 23 appropriately come into contact with the battery terminal 211 of the battery module 210, the connection determination bar 81 is positioned in an appropriate connection range 82a of the gauge 82.

Meanwhile, as shown in FIG. 11C, for example, when a foreign matter 250 enters a place between the probes 23 and the battery terminal 211 of the battery module 210, the end surfaces of the probes 23 on the side opposite from the battery terminal side are further put out to the inside of the battery terminal connection portion base 22. In this case, the connection determination bar 81 of the connection determination unit 80 further rotates about the connection determination bar supporting portion 84 and is positioned outside the range of the appropriate connection range 82a of the gauge 82, and a state in which the probes 23 are not appropriately connected to the battery terminal 211 can be checked. It can be determined whether the plurality of probes 23 is appropriately connected to the battery terminals 211 on the basis of the positions of the plurality of connection determination bars 81 with respect to the gauges 82 when viewed from the stacking direction (X-axial direction) of the battery modules 210.

### Second Embodiment

While a case in which the fastening clamps 60 are used to connect the battery terminal connection portions 20 to the plurality of battery terminals 211 of the plurality of battery modules 210 has been described in the first embodiment, a case in which fixing bolts 61 and fixing nuts 62 are used for the connection is described in the second embodiment. Sections similar to those in the first embodiment are denoted by the same reference characters, and description thereof is omitted.

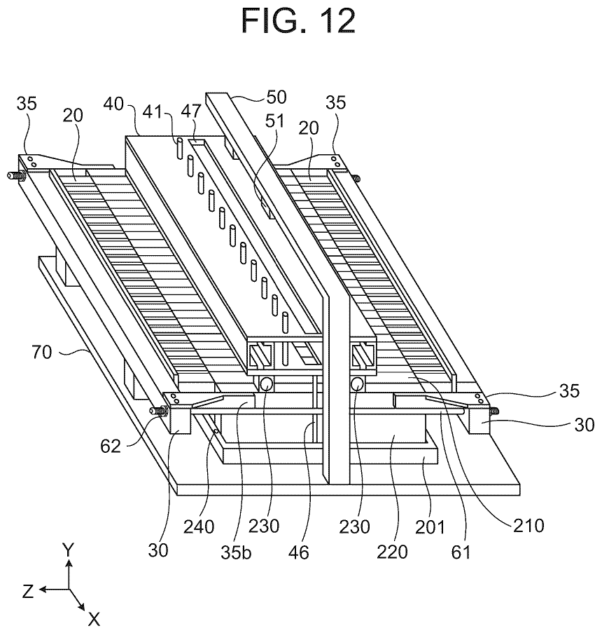

FIG. 12 is a view showing an overview of a battery measurement jig according to the second embodiment. As shown in FIG. 12, the battery measurement jig according to the second embodiment has the plurality of battery terminal connection portions 20, the flat bars 30, the positioning boards 35, the temperature measurement jig 40, the battery ID reading unit 50, the fixing bolts 61 (can be considered as one example of a “second fastening member” in the claims), the fixing nuts 62, the battery installation stand 70, and the battery unit fixing frame 201.

Regarding the flat bars 30, the fixing bolts 61 are caused to pass through through-holes provided in the flat bars 30, and the battery terminal connection portions 20 are connected to the battery terminals 211 of the battery modules 210 with use of the fixing nuts 62.

As described above, in the present second embodiment, the fixing bolts 61 are caused to pass through the through-holes provided in the flat bars 30, and the battery terminal connection portions 20 are connected to the battery terminals 211 of the battery modules 210 with use of the fixing nuts 62. Therefore, the space occupied by the entire battery measurement jig can be reduced.

Each configuration illustrated in each embodiment is a functional outline,

and does not necessarily need to physically have the illustrated configuration. In other words, the form of distribution and integration of each apparatus is not limited to those illustrated, and all or some thereof can be configured by being functionally or physically distributed and integrated in freely-selected units in accordance with various loads and usage situations.

The battery measurement jig and the temperature measurement jig according to the present disclosure are suitable for a case of efficiently measuring the performance of a plurality of batteries while reducing human effort necessary for position adjustment of battery terminals.

What is claimed is:

1. A battery measurement jig, comprising:
a plurality of battery terminal connection portions, each of the battery terminal connection portions including
a battery terminal connection portion base including a probe configured to be connected to a battery terminal being a part of a battery, and
a battery terminal guide; and
a flat bar, wherein,
the battery terminal connection portions are arranged on the flat bar,
the battery terminal guide is combined with the battery terminal connection portion base so as to be configured to slide in a battery terminal direction of the battery, and
the battery terminal connection portion base is provided on the flat bar with a clearance so as to be configured to move in a direction perpendicular to the battery terminal direction of the battery.

2. The battery measurement jig according to claim 1, wherein:
the battery terminal guide includes
a first elastic body that supports the battery terminal guide with respect to the battery terminal connection portion base, and
a tapered-shape hole that guides the battery terminal;
a second elastic body is provided in the probe;
the probe is configured to slide in the battery terminal direction of the battery;
the battery terminal connection portion base is installed on the flat bar by a first fastening member such that a gap is provided between the flat bar and the battery terminal connection portion base; and
a diameter of an attachment hole provided on the flat bar or the battery terminal connection portion base is greater than a diameter of the first fastening member such that the first fastening member is configured to move in a two-dimensional manner in a direction perpendicular to the battery terminal direction.

3. The battery measurement jig according to claim 1, wherein each of the battery terminal connection portions installed on the flat bar is connected to the battery terminal of the battery by a fastening clamp at a constant pressure.

4. The battery measurement jig according to claim 1, wherein each of the battery terminal connection portions installed on the flat bar is connected to the battery terminal of the battery by a second fastening member.

5. The battery measurement jig according to claim 3, wherein, regarding attachment between the flat bar and the battery terminal connection portion base, an attachment hole on the flat bar or an attachment hole on the battery terminal connection portion base has an elliptical shape having a long axis in a direction perpendicular to a stacking direction of batteries and the battery terminal direction of the battery.

6. The battery measurement jig according to claim 3, wherein a battery terminal side distal end of the probe is positioned closer to the battery terminal connection portion base than a terminal side end portion of the battery terminal guide is in a state before each of the battery terminal connection portions is connected to the battery terminal, and the probe is connected to the battery terminal after the battery terminal is inserted into a tapered-shape hole and the battery terminal guide comes into contact with the battery terminal.

7. The battery measurement jig according to claim 3, wherein:
a connection determination bar is provided on the battery terminal connection portion base via a third elastic body;
the battery terminal guide includes a gauge;
the connection determination bar is configured to be inclined to the battery terminal guide in accordance with a pushing amount of the probe; and
whether the probe is appropriately connected to the battery terminal is determined based on a position of the connection determination bar with respect to the gauge when viewed from a stacking direction of batteries.

8. A battery measurement jig, comprising:
a plurality of battery terminal connection portions respectively including probes configured to be connected to battery terminals of a plurality of batteries configuring a battery unit coupled by a pair of coupling plates; and
a flat bar, wherein
a placing position of the battery unit is positioned with use of a protrusion or a screw hole provided on a battery unit fixing frame provided on a predetermined battery installation stand,
the battery terminal connection portions that respectively abut against the battery terminals of the batteries are positioned by moving a positioning board provided on the flat bar along the coupling plates, and
the battery terminals of the batteries and the probes of the battery terminal connection portions are connected to each other by a fastening clamp provided on the predetermined battery installation stand.

9. A temperature measurement jig configured such that a thermistor is inserted into a temperature measurement hole in a battery by sliding and measures a temperature of the battery, comprising:
an upper plate that supports the thermistor; and
a lower plate that supports the thermistor, wherein,
the thermistor includes a fourth elastic body, is positioned in an inner side of an upper plate hole provided in the upper plate and a lower plate hole provided in the lower plate, and is provided in the temperature measurement hole in the battery, and
each of a diameter of the upper plate hole and a diameter of the lower plate hole is greater than a diameter of the thermistor such that the thermistor is configured to move in a direction perpendicular to a sliding direction.

10. The temperature measurement jig according to claim 9, wherein the diameter of the lower plate hole is greater than the diameter of the upper plate hole.
